(19) United States
(12) Patent Application Publication
(10) Pub. No.: US 2025/0056921 A1
(43) Pub. Date: Feb. 13, 2025

(54) Hybrid Bonding With Micro-Light Emitting Diode (LED) Devices

(71) Applicant: Lumileds LLC, San Jose, CA (US)

(72) Inventors: Erik William Young, San Jose, CA (US); Rajiv Pathak, Milpitas, CA (US)

(73) Assignee: Lumileds LLC, San Jose, CA (US)

(21) Appl. No.: 18/720,857

(22) PCT Filed: Dec. 13, 2022
(86) PCT No.: PCT/US2022/081422

§ 371 Date: Jun. 17, 2024

Related U.S. Application Data
(62) Division of application No. 63/320,835, filed on Mar. 17, 2022.
(60) Provisional application No. 63/386,355, filed on Dec. 7, 2022.
(60) Provisional application No. 63/295,615, filed on Dec. 31, 2021.

(51) Int. Cl. H01L 33/00; H01L 25/075; H01L 25/16; H01L 27/15; H01L 33/62

(52) U.S. Cl. CPC H01L 33/0093; H01L 25/167; H01L 27/156; H01L 33/62; H01L 25/0753; H01L 2933/0066

(57) ABSTRACT

Micro-light emitting diode (uLED) devices comprise: a source wafer comprising a uLED die bonded to a target wafer. Wafer n-contacts are directly bonded to a plurality of die n-contacts; wafer p-contacts are directly bonded to die p-contacts; and wafer dielectric material is directly bonded to die dielectric material; the wafer dielectric material isolates the wafer n-contacts and the wafer p-contacts.

### TECHNICAL FIELD

Embodiments of the disclosure generally relate to micro-light emitting diode (uLED) devices, and methods of manufacturing and using the same. The uLED devices comprise: hybrid bonding in that there is a combination of a metal-to-metal bonds and dielectric-to-dielectric bonds between a source wafer and a target wafer.

### BACKGROUND

Semiconductor light-emitting devices or optical power emitting devices (such as devices that emit ultraviolet (UV) or infrared (IR) optical power), including light emitting diodes, resonant cavity light emitting diodes, vertical cavity laser diodes, and edge emitting lasers, are among the most efficient light sources currently available. Due to their compact size and lower power requirements, for example, semiconductor light or optical power emitting devices (referred to herein as LEDs for simplicity) are attractive candidates for light sources, such as camera flashes, for hand-held battery-powered devices, such as cameras and cell phones. They may also be used, for example, for other applications, such as for automotive lighting, torch for video, and general illumination, such as home, shop, office and studio lighting, theater/stage lighting and architectural lighting.

High-intensity/brightness light emitting devices capable of operation across the visible spectrum include Group III-V semiconductors, particularly binary, ternary, and quaternary alloys of gallium, aluminum, indium, and nitrogen, also referred to as III-nitride materials. Typically, Ill-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region.

Various emerging display applications, including wearable devices, head-mounted, and large-area displays require miniaturized chips composed of arrays of microLEDs (μLEDs or uLEDs) with a high density having a lateral dimension down to less than 100 μm×100 μm. MicroLEDs (uLEDs) typically have dimensions of about 50 μm in diameter or width and smaller that are used to in the manufacture of color displays by aligning in close proximity microLEDs comprising red, blue and green wavelengths.

Present design architectures of arrays of microLEDs and their pixels present challenges in handling and electrical testing due to their micro-sizes.

There is a need to assemble microLED devices reliably and efficiently.

### SUMMARY

Provided herein are micro-light emitting diode (uLED) devices, and methods of manufacturing and using the same.

An aspect provides: a micro-light emitting diode (uLED) device comprising: a source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts; a target wafer comprising: a target substrate on which a plurality of wafer n-contacts, a plurality of wafer p-contacts, and a wafer dielectric material are located, the wafer n-contacts directly bonded to the plurality of die n-contacts; the wafer p-contacts directly bonded to the die p-contacts; and the wafer dielectric material directly bonded to the die dielectric material; the wafer dielectric material isolating the wafer n-contacts and the wafer p-contacts.

Another aspect is: a method of manufacturing a micro-light emitting diode (uLED) device comprising: preparing a target wafer comprising: a target substrate on which a plurality of wafer n-contacts, a plurality of wafer p-contacts, and a wafer dielectric material are located; bonding a source wafer to the target wafer, the source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts, and upon bonding, the plurality of the wafer n-contacts are directly bonded to the plurality of die n-contacts; the plurality of wafer p-contacts are directly bonded to the die p-contacts; and the wafer dielectric material directly is bonded to the die dielectric material. The target wafer is prepared by: depositing an etch stop layer on the target substrate; depositing a primary dielectric material on the target substrate; preparing a dielectric material mask on the target substrate, etching the primary dielectric material, and removing the dielectric material mask; preparing a primary metal contact layer on the target substrate; planarizing a preliminary surface of the target substrate; depositing a secondary dielectric material layer on the target substrate, preparing a contact mask on the target substrate, etching the secondary dielectric material, and removing the contact mask; preparing a secondary metal contact layer on the target substrate; and planarizing a second surface of the target substrate to form the plurality of wafer n-contacts and the plurality of wafer p-contacts, which are isolated by the wafer dielectric material.

Another aspect is a source wafer comprising: a uLED die including: a stack of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts; each of the die n-contacts and the die p-contacts having a contact opening having a diameter “d” and a center “c”, and a pitch “p” between adjacent centers of each of the die n-contacts and the die p-contacts, the “d” being in a range of greater than or equal to 0.5 micrometers and less than or equal to 30 micrometers, and the “p” being in a of greater than or equal to 1 micrometer and less than or equal to 60 micrometers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating in an expanded cross-section a portion of a micro-light emitting diode (uLED) device according to one or more embodiments;

FIG. 2 provides a process flow diagram for manufacture of a micro-light emitting diode (uLED) device according to one or more embodiments;

FIG. 3 illustrates a top view of an exemplary display device according to one or more embodiments;

FIG. 4 schematically illustrates an exemplary display system comprising uLED devices according to embodiments herein;

FIG. 5 provides a process flow diagram for manufacture of source wafer according to one or more embodiments;

FIG. 6 shows a block diagram of a visualization system according to one or more

embodiments; and

FIG. 7 is a schematic plan view of an exemplary series of metal contacts denoting diameter (“d”), center (“c”), and pitch (“p”).

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of ±1-5%. In a preferred embodiment, one or more dimensions of height, width, depth, thickness have values of 200 micrometers ±1-5%. In some instances, the LEDs are referred to as micro-LEDs (uLEDs or μLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometers to 300 micrometers, and all values and sub-ranges therebetween.

Methods of depositing materials, layers, and thin films include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type and/or N-type layer, active region, and p-type and/or P-type layer are formed according to methods known in the art. In one or more embodiments, the semiconductor layers are formed by epitaxial (EPI) growth. The semiconductor layers according to one or more embodiments comprise epitaxial layers, III-nitride layers, or epitaxial III-nitride layers. In one or more embodiments, the semiconductor layers comprise a III-nitride material, and in specific embodiments epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN) and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

Decreasing sizes of LEDs, with particular in regard to micro-LEDs (uLEDs), imposes processing challenges. Ensuring proper electrical continuity of the structures is one such challenge. Preparing target and source wafers for bonding contributes to proper electrical continuity of the structures.

Suitable applications for uLED devices herein include but are not limited to augmented reality/virtual reality (AR/VR) systems. One or more AR/VR systems include: augmented (AR) or virtual reality (VR) headsets, glasses, or projectors.

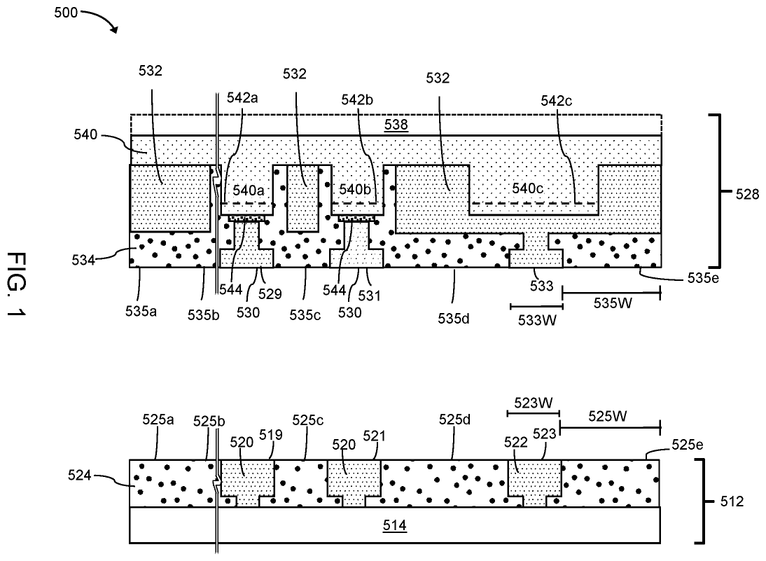

FIG. 1 is a schematic view illustrating in an expanded cross-section a portion of a micro-light emitting diode (uLED) device according to one or more embodiments.

The uLED device 500 comprises a target wafer 512 and a source wafer 528. The portion of the target wafer 512 shown comprises: a target substrate 514, a plurality of target metal contacts 520, for example p-metal contacts, a target dielectric material 524 isolating the target metal contacts 520 and a n-metal contact 522. Optionally, an etch stop layer (not shown) may be located on the target substrate 512 below the target metal contacts 520 and 522, and the target dielectric material 524. In one or more embodiments, the etch stop layer is a dielectric material that is different from the dielectric material 524 isolating the target metal contacts 520 and a n-metal contact 522. In one or more embodiments, the target wafer is a complementary metal-oxide-semiconductor (CMOS).

The source wafer 528, which is an active micro-structure die in this embodiment, including semiconductor layers 540 that have been pixelated into pixels 540a, 540b, and 540c, for example. The pixels 540a, 540b, and 540c include respective active regions 542a, 542b, and 542c, and n-type layers and p-type layers (not numbered). The source wafer 528 includes a plurality of die metal contacts 530, for example, p-metal contacts, and metal contact 532, for example, a n-metal contact, in particular, a common cathode, and a die dielectric material 534 providing isolation there between. In one or more embodiments, a source substrate 538 is positioned adjacent to the semiconductor layers 540. Dielectric material insulates the n-type layers and the p-type layers as understood in the art to ensure electrical functionality and suitable communication with the respective n-contact material and/or cathode and p-contact material and/or anode.

In the expanded view of FIG. 1, surfaces are shown as “exposed” in that prior to bonding to form the uLED device, the surfaces are accessible for a bonding process. Upon assembly, bonding occurs at and between the exposed surfaces.

The target metal p-metal contacts 520 of the target wafer 512 each has exposed surfaces 519 and 521, respectively. The target metal n-metal contact 522 of the target wafer 512 has exposed surface 523.

The die p-metal contacts 530 of the source wafer 528 each has exposed surfaces 529 and 531, respectively. The die n-metal contact 532 of the source wafer 528 has exposed surface 533.

For assembly of the uLED device, a process to achieve hybrid bonding is conducted. Reference to hybrid bonding means that there is a combination of a metal-to-metal bonds and dielectric-to-dielectric bonds.

Target dielectric material surface 525a bonds to die dielectric material surface 535a; target dielectric material surface 525b bonds to die dielectric material surface 535b; target dielectric material surface 525c bonds to die dielectric material surface 535c; target dielectric material surface 525d bonds to die dielectric material surface 535d; and target dielectric material surface 525e bonds to die dielectric material surface 535e. Each of the die dielectric material surfaces has a width, and likewise, each of the target dielectric material surfaces has a width. As an example illustrated in FIG. 1, the die dielectric material surface 535e has a width 535W which is directly bonded to the target dielectric material surface 525e which as a width 525W.

The target p-metal contact surface 519 bonds to the die p-metal contact surface 529; the target p-metal contact surface 521 bonds to the die p-metal contact surface 531; the target n-metal contact surface 523 bonds to the die n-metal contact surface, e.g., the common cathode, 533. Each of the die metal contact surfaces, namely p-metal contact surfaces and the n-metal contact surface, has a width or diameter, and likewise, each of the target metal contact surfaces has a width or diameter. As an example illustrated in FIG. 1, the die n-metal contact surface 533 has a width 533W (or diameter) which is directly bonded to the target n-metal contact surface 523 which as a width 523W (or diameter).

In one or more embodiments, a width of each of the wafer n-contacts is 95% to 100%, and all values and subranges therebetween of a width of each of the die n-contacts at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

In one or more embodiments, a width of each of the wafer p-contacts is 95% to 100% of a width of each of the die p-contacts at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

In one or more embodiments, a width of the wafer dielectric material is 95% to 100% of a width of the die dielectric material at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

In one or more embodiments, a width of each of the wafer n-contacts is 95% to 100% of a width of each of the die n-contacts at each location where they are directly bonded; a width of each of the wafer p-contacts is 95% to 100% of a width of each of the die p-contacts at each location where they are directly bonded; and a width of the wafer dielectric material is 95% to 100% of a width of the die dielectric material at each location where they are directly bonded, including 95.5%, 96%, 96.5%, 97%, 97.5%, 98%, 98.5%, 99%, 99.1%, 99.2%, 99.2%, 99.3%, 99.4%, 99.5%, 99.6%, 99.7%, 99.8%, 99.9%.

Upon bonding of the source wafer 528 to the target wafer 512, the uLED device 500 is formed.

In one or more embodiments, the target metal contacts comprise one or more of: copper (Cu), aluminum (Al), nickel (Ni), titanium (Ti), titanium-tungsten (TiW), silver (Ag), gold (Au), platinum (Pt), and palladium (Pd).

In one or more embodiments, the target wafer comprises an etch stop layer on the target substrate below the target metal contacts and the first target dielectric material. In one or more embodiments, the etch stop layer comprises a second dielectric material different from the first target dielectric material. In one or more embodiments, the first target dielectric material comprise one or more of: silicon oxide (SiO), silicon dioxide (SiO₂), silicon nitride (SiN), silicon carbide (SiC), aluminum oxide (Al₂O₃), and aluminum nitride (AlN). An exemplary etch stop layer comprises SiN, in which case the first target dielectric material would comprise one or more of: silicon oxide (SiO), silicon dioxide (SiO₂), silicon nitride (SiN), silicon carbide (SiC), and aluminum oxide (Al₂O₃).

In one or more embodiments, die dielectric material comprises one or more of: silicon oxide (SiO), silicon dioxide (SiO₂), silicon nitride (SiN), silicon carbide (SiC), aluminum oxide (Al₂O₃), and aluminum nitride (AlN).

In one or more embodiments, the target substrate comprises a material selected from the group consisting of: ceramic, silicon, aluminum, sapphire, silicon carbide, and III-nitride.

In one or more embodiments, the uLED die further comprises a die substrate in contact with the semiconductor layers including the active region. In some embodiments, the die substrate comprises a material selected from the group consisting of: a sapphire, silicon carbide, and III-nitride.

In one or more embodiments, the die substrate comprises a material selected from the group consisting of: ceramic, silicon, aluminum, sapphire, silicon carbide, and III-nitride.

In one or more embodiments, the wafer n-contacts are directly bonded to the plurality of die n-contacts over respective n-contact bond areas and the wafer p-contacts are directly bonded to the die p-contacts over respective p-contact bond areas, and wherein diameters of the n-contact bond areas and the p-contact bond areas have a diameter in a range of 0.5 micrometers to less than or equal to 30 micrometers, including all values and subranges therebetween.

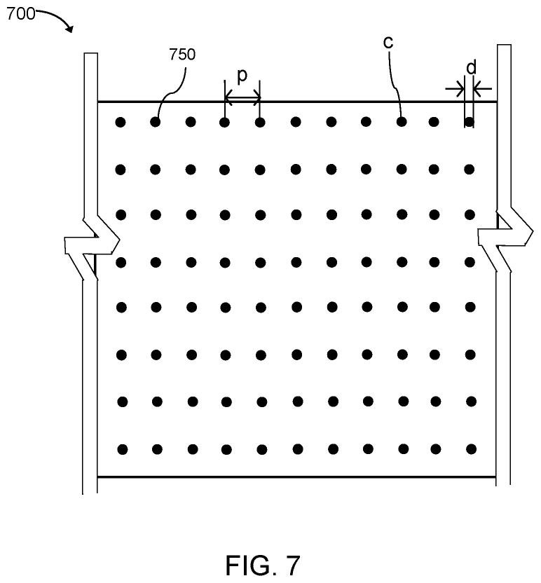

In one or more embodiments, the wafer n-contacts are directly bonded to the plurality of die n-contacts over respective n-contact bond areas and the wafer p-contacts are directly bonded to the die p-contacts over respective p-contact bond areas, and wherein a pitch between centers of all of the n-contact bond areas and the p-contact bond areas is in a range of greater than or equal to 1 micrometers to less than or equal to 60 micrometers, including all values and subranges therebetween. FIG. 7 a schematic plan view of an exemplary series of metal contacts 750 of a portion of a die 700 denoting diameter (“d”), center (“c”), and pitch (“p”). It is understood that in one or more embodiments, the common cathode may be sized differently from the plurality of n-contacts and would not be included when discussion pitch between contacts.

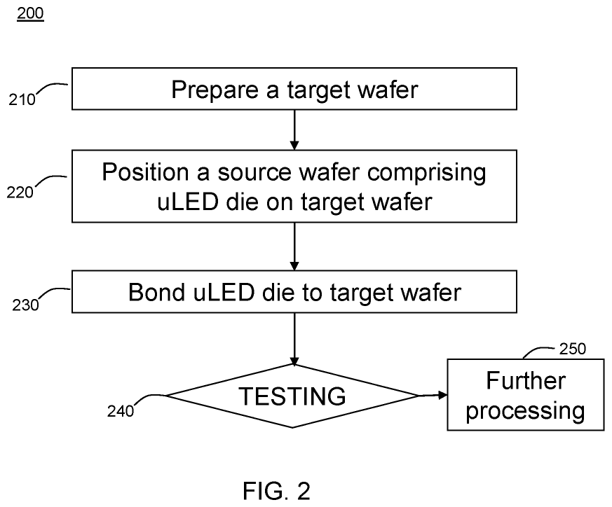

FIG. 2 provides a process flow diagram for manufacture 200 of the micro-light emitting diode (uLED) devices according to one or more embodiments. At operation 210, a target wafer is prepared. Features of the target wafer are prepared as follows.

An etch stop layer is deposited on a target substrate of the target wafer. A primary dielectric material is deposited on the target substrate. A dielectric material mask of, for example, a photoresist material, is prepared on the target substrate, then the primary dielectric material is etched in a pattern to the etch stop layer to create areas for receipt of a primary metal contact material, and the dielectric material mask is removed, which results in the preparation or formation of a primary dielectric material layer.

Thereafter, the primary metal contact material is prepared on the target substrate. In one or more embodiments, preparing of the primary metal contact layer comprises depositing a seed layer and thereafter conducting metal plating on the seed layer. A preliminary surface of the target substrate including the primary metal contact material is planarized to prepare a primary metal contact layer. This planarization technique seeks to provide less than or equal to 5 Å planarity. In one or more embodiments, the planarization step includes chemical mechanical polishing (CMP). Upon completion of the planarization, cleaning and/or removal of particles may be conducted to a desired specification, elimination of residual metal and other debris. Thereafter, a secondary dielectric material is prepared and/or deposited on the target substrate.

Thereafter, a contact mask is prepared on the target substrate. The contact mask is a result of light treatment of photoresist through a transmission mask and partial removal thereafter. Contact opening templates of the contact mask are used to block dielectric material from reaching the substrate during deposition of the dielectric material. In one or more embodiments, the contact mask comprises a mask body in which a plurality of metal contact opening templates are formed. Each of the metal contact opening templates has a diameter (“d”). There is a pitch between centers of each of the metal contact opening templates (“p”).

The secondary dielectric material is etched in a pattern to prepare areas for receipt of a secondary metal contact metal. The contact mask is then removed, which prepares and/or forms a secondary dielectric material layer. Some portions of the secondary dielectric material layer are in combination with the first dielectric material layer and span from the etch stop layer to an exposed surface. Thereafter, the secondary metal contact material is prepared on the target substrate. In one or more embodiments, preparing of the secondary metal contact layer comprises depositing a seed layer and thereafter conducting metal plating on the seed layer.

A second surface of the target substrate including the secondary metal contact material is then planarized to form a plurality of target metal contacts including a beginning contact area and an ending contact area, isolated by the primary and secondary dielectric material layers. Planarizing the second surface of the target substrate seeks to provide less than or equal to 5 Å planarity. In one or more embodiments, this planarization step includes chemical mechanical polishing (CMP). Upon completion of the planarization, cleaning and/or removal of particles may be conducted to a desired specification, elimination of residual metal and other debris. In one or more embodiments, preparing of the secondary metal contact layer comprises depositing a seed layer and conducting metal plating on the seed layer.

At operation 220, a source wafer comprising a uLED die is positioned on the target wafer.

At operation 230, the uLED die is bonded to the target wafer. In one or more embodiments, upon the bonding of uLED die to the target wafer, the die n-contacts and the die p-contacts are connected in series to the wafer n-contacts and the wafer p-contacts.

Thereafter, at operation 240, quality control testing is conducted. In one or more embodiments, bonds between the target metal contacts and the die metal contacts are evaluated. In one or more embodiments, bonds between the first target dielectric material and the die dielectric material are evaluated.

At operation 250, optional further post-processing is performed. In one or more embodiments, further processing includes formation of a passivation layer around a portion or the entirety of one or more uLEDs or the uLED device as a whole. In one or more embodiments, the processed structure retains a substrate, is singulated, and is further processed. In one or more embodiments, the processed structure is flipped and affixed to a support, for example, a tape support, and the substrate is removed. Removal of the substrate is in accordance with methods known in the art including substrate laser liftoff. Upon removal of the substrate, singulated LEDs or uLEDs are created.

Further processing can include deposition of a down-converter material, e.g. layers of a phosphor material.

In some embodiments, LED devices herein are further processed to include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

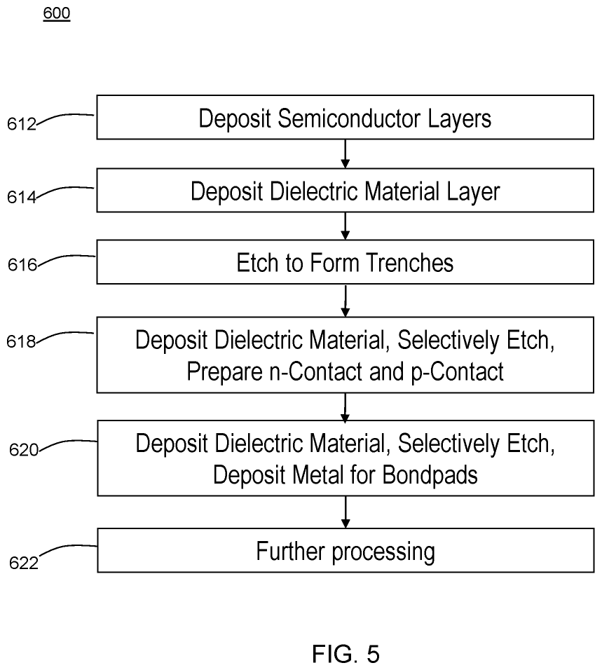

FIG. 5 provides a process flow diagram for manufacture 600 of an exemplary source wafer according to one or more embodiments, for example source wafer 528 of FIG. 1. The method 600 comprises at 612 depositing a plurality of semiconductor layers including an n-type layer, an active region, and a p-type layer on a substrate. At 614, the method further comprises depositing a dielectric material as a hard mask layer. At 616, the method further comprises etching a portion of hard mask layer and the semiconductor layers to form trenches and a plurality of spaced mesas defining pixels, each of the plurality of spaced mesas comprising the semiconductor layers. At 618, the method comprises depositing a second dielectric material conformal to sidewalls of the p-type layer and the active region; and selectively etching and depositing metal to prepare n-contact and p-contact materials in a space between each of the plurality of spaced mesas. The second dielectric material insulates the p-type layer and the active region from the n-contact material. At 620, the method comprises depositing third dielectric material and selectively etching and depositing electrode metal for bondpads.

At operation 622, further processing is conducted. Further processing could include removing the substrate and flipping the die. Other processing could include deposition of a down-converter material, e.g. layers of a phosphor material. In some embodiments, LED arrays herein are further processed to include optical elements such as lenses, metalenses, and/or pre-collimators.

### uLED DEVICES

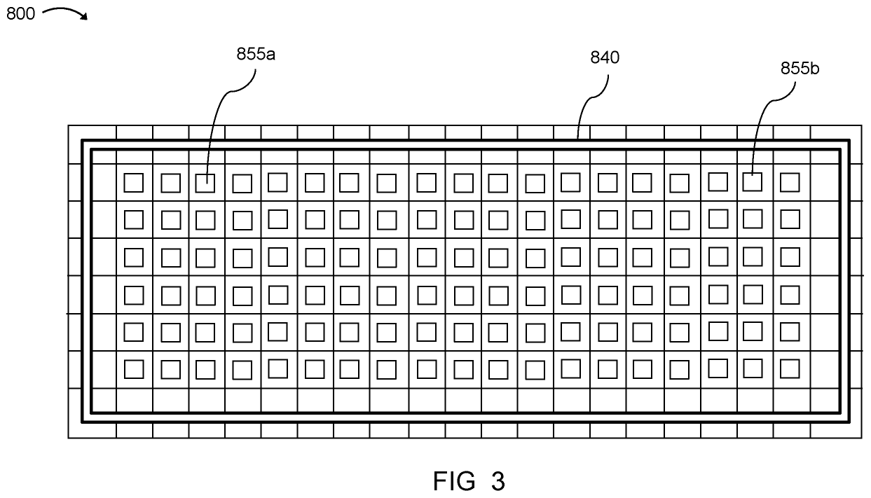

FIG. 3 shows a top plan view of an exemplary uLED display device comprising a uLED monolithic array 800 comprising a plurality of pixels arranged in a grid of 6×19. Pixels 855a and 855b are examples. In this embodiment, a common cathode 840 is connected to the pixels. Anodes, not shown, present on the underside are included with each pixel. In one or more embodiments, the array comprises an arrangement of 2×2 mesas, 4×4 mesas, 20×20 mesas, 50×50 mesas, 100×100 mesas, or n1×n2 mesas, where each of n1 and n2 is a number in a range of from 2 to 1000, and n1 and n2 can be equal or not equal.

In one or more embodiments, arrays of micro-LEDs (μLEDs or uLEDs) are used. Micro-LEDs can support high density pixels having a lateral dimension less than 100 μm by 100 μm. In some embodiments, micro-LEDs with dimensions of about 50 μm in diameter or width and smaller can be used. Such micro-LEDs can be used for the manufacture of color displays by aligning in close proximity micro-LEDs comprising red, blue and green wavelengths.

In some embodiments, the light emitting arrays include small numbers of micro-LEDs positioned on substrates that are centimeter scale area or greater. In some embodiments, the light emitting arrays include micro-LED pixel arrays with hundreds, thousands, or millions of light emitting LEDs positioned together on centimeter scale area substrates or smaller. In some embodiments, micro-LEDs can include light emitting diodes sized between 30 microns and 500 microns. The light emitting array(s) can be monochromatic, RGB, or other desired chromaticity. In some embodiments, pixels can be square, rectangular, hexagonal, or have curved perimeter. Pixels can be of the same size, of differing sizes, or similarly sized and grouped to present larger effective pixel size.

In some embodiments, light emitting pixels and circuitry supporting light emitting arrays are packaged and optionally include a submount or printed circuit board connected for powering and controlling light production by semiconductor LEDs. In certain embodiments, a printed circuit board supporting light emitting array includes electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the light emitting array and a power supply, and also provide heat sink functionality.

In some embodiments, LED light emitting arrays include optical elements such as lenses, metalenses, and/or pre-collimators. Optical elements can also or alternatively include apertures, filters, a Fresnel lens, a convex lens, a concave lens, or any other suitable optical element that affects the projected light from the light emitting array. Additionally, one or more of the optical elements can have one or more coatings, including UV blocking or anti-reflective coatings. In some embodiments, optics can be used to correct or minimize two-or three dimensional optical errors including pincushion distortion, barrel distortion, longitudinal chromatic aberration, spherical aberration, chromatic aberration, field curvature, astigmatism, or any other type of optical error. In some embodiments, optical elements can be used to magnify and/or correct images. Advantageously, in some embodiments magnification of display images allows the light emitting array to be physically smaller, of less weight, and require less power than larger displays. Additionally, magnification can increase a field of view of the displayed content allowing display presentation equals a user's normal field of view.

### Applications

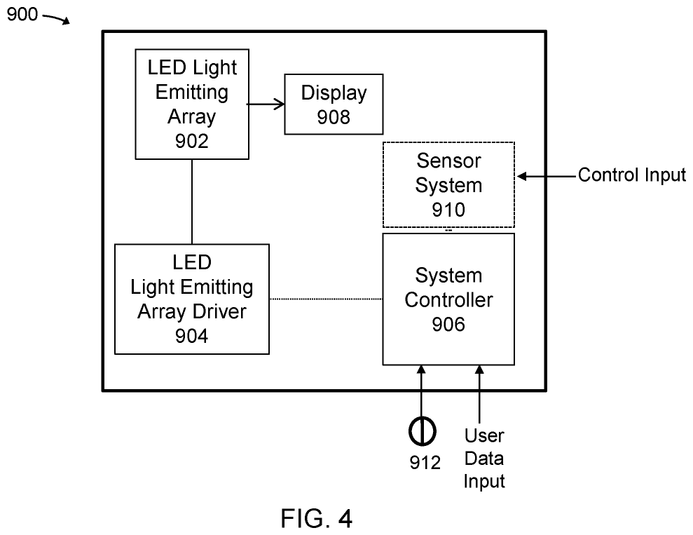

FIG. 4 schematically illustrates an exemplary display system 900 utilizing LEDs, including uLEDs, disclosed herein. The display system 900 comprises an LED light emitting array 902 and display 908 in electrical communication with an LED driver 904. The display system 900 also comprises a system controller 906, such as a microprocessor. The controller 906 is coupled to the LED driver 904. The controller 906 may also be coupled to the display 908 and to optional sensor(s) 910, and be powered by power source 912. In one or more embodiments, user data input is provided to system controller 906.

In one or more embodiments, the system is a camera flash system utilizing uLEDs. In such an embodiment, the LED light emitting array 902 is an illumination array and lens system and the display 908 comprises a camera, wherein the LEDs of 902 and the camera of 908 may be controlled by the controller 906 to match their fields of view.

Optionally sensors 910 with control input may include, for example, positional sensors (e.g., a gyroscope and/or accelerometer) and/or other sensors that may be used to determine the position, speed, and orientation of system. The signals from the sensors 910 may be supplied to the controller 906 to be used to determine the appropriate course of action of the controller 906 (e.g., which LEDs are currently illuminating a target and which LEDs will be illuminating the target a predetermined amount of time later).

In operation, illumination from some or all of the pixels of the LED array in 902 may be adjusted—deactivated, operated at full intensity, or operated at an intermediate intensity. As noted above, beam focus or steering of light emitted by the LED array in 902 can be performed electronically by activating one or more subsets of the pixels, to permit dynamic adjustment of the beam shape without moving optics or changing the focus of the lens in the lighting apparatus.

LED array systems such as described herein may support various other beam steering or other applications that benefit from fine-grained intensity, spatial, and temporal control of light distribution. These applications may include, but are not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. Associated optics may be distinct at a pixel, pixel block, or device level. An example light emitting pixel array may include a device having a commonly controlled central block of high intensity pixels with an associated common optic, whereas edge pixels may have individual optics. In addition to flashlights, common applications supported by light emitting pixel arrays include video lighting, automotive headlights, architectural and area illumination, and street lighting.

Other applications of LED devices herein include augmented reality/virtual reality (AR/VR) systems, which may utilize uLEDs disclosed herein. One or more AR/VR systems include: augmented (AR) or virtual reality (VR) headsets, glasses, or projectors. Such AR/VR systems includes an LED light emitting array, an LED driver (or light emitting array controller), a system controller, an AR or VR display, a sensor system 810. Control input may be provided to the sensor system, while power and user data input is provided to the system controller. As will be understood, in some embodiments modules included in the AR/VR system can be compactly arranged in a single structure, or one or more elements can be separately mounted and connected via wireless or wired communication. For example, the light emitting array, AR or VR display, and sensor system can be mounted on a headset or glasses, with the LED driver and/or system controller separately mounted.

In one embodiment, the light emitting array can be used to project light in graphical or object patterns that can support AR/VR systems. In some embodiments, separate light emitting arrays can be used to provide display images, with AR features being provided by a distinct and separate micro-LED array. In some embodiments, a selected group of pixels can be used for displaying content to the user while tracking pixels can be used for providing tracking light used in eye tracking. Content display pixels are designed to emit visible light, with at least some portion of the visible band (approximately 400 nm to 750 nm). In contrast, tracking pixels can emit light in visible band or in the IR band (approximately 750 nm to 2,200 nm), or some combination thereof. As an alternative example, the tracking pixels could operate in the 800 to 1000 nanometer range. In some embodiments, the tracking pixels can emit tracking light during a time period that content pixels are turned off and are not displaying content to the user.

The AR/VR system can incorporate a wide range of optics in the LED light emitting array and/or AR/VR display, for example to couple light emitted by the LED light emitting array into AR/VR display as discussed above. For AR/VR applications, these optics may comprise nanofins and be designed to polarize the light they transmit.

In one embodiment, the light emitting array controller can be used to provide power and real time control for the light emitting array. For example, the light emitting array controller can be able to implement pixel or group pixel level control of amplitude and duty cycle. In some embodiments, the light emitting array controller further includes a frame buffer for holding generated or processed images that can be supplied to the light emitting array. Other supported modules can include digital control interfaces such as Inter-Integrated Circuit (I2C) serial bus, Serial Peripheral Interface (SPI), USB-C, HDMI, Display Port, or other suitable image or control modules that are configured to transmit needed image data, control data or instructions.

In operation, pixels in the images can be used to define response of corresponding light emitting array, with intensity and spatial modulation of LED pixels being based on the image(s). To reduce data rate issues, groups of pixels (e.g. 5×5 blocks) can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. Pulse width modulation can be used to control each pixel to emit light in a pattern and with an intensity at least partially dependent on the image.

In some embodiments, the sensor system can include external sensors such as cameras, depth sensors, or audio sensors that monitor the environment, and internal sensors such as accelerometers or two or three axis gyroscopes that monitor AR/VR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position. As another example, based on the one or more measurement signals from one or more gyroscope or position sensors that measure translation or rotational movement, an estimated position of AR/VR system relative to an initial position can be determined.

In some embodiments, the system controller uses data from the sensor system to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow.

Based on changes in position, orientation, or movement of the AR/VR system, the system controller can send images or instructions the light emitting array controller. Changes or modification in the images or instructions can also be made by user data input, or automated data input as needed. User data input can include but is not limited to that provided by audio instructions, haptic feedback, eye or pupil positioning, or connected keyboard, mouse, or game controller.

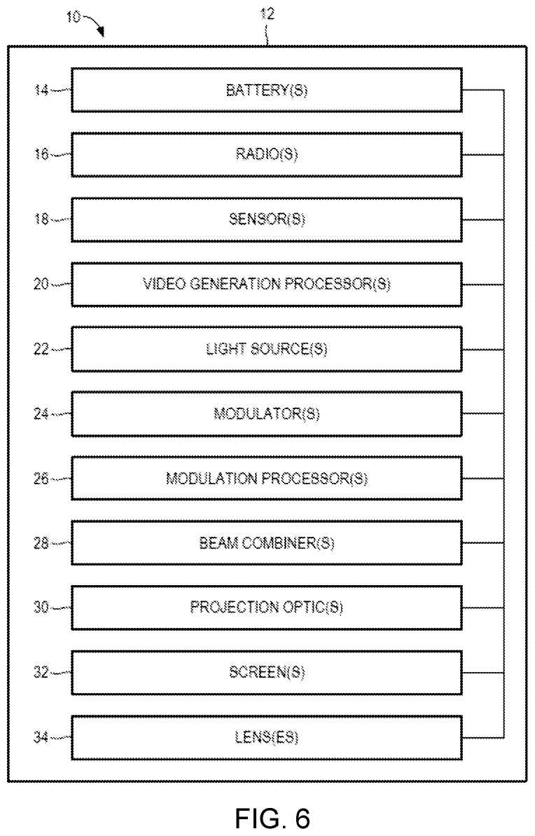

FIG. 6 shows a block diagram of an example of a visualization system 10. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive, from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, that represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

### EMBODIMENTS

Various embodiments are listed below. It will be understood that the embodiments listed below may be combined with all aspects and other embodiments in accordance with the scope of the invention.

Embodiment (a). A micro-light emitting diode (uLED) device comprising: a source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with ta p-type layer of the mesa; and a die dielectric material isolating the die n-contacts and the die p-contacts; a target wafer comprising: a target substrate on which a plurality of wafer n-contacts, a plurality of wafer p-contacts, and a wafer dielectric material are located, the wafer n-contacts directly bonded to the plurality of die n-contacts; the wafer p-contacts directly bonded to the die p-contacts; and the wafer dielectric material directly bonded to the die dielectric material; the wafer dielectric material isolating the wafer n-contacts and the wafer p-contacts.

Embodiment (b). The uLED device of embodiment (a), wherein the die n-contacts, the wafer n-contacts, the die p-contacts and the wafer p-contacts comprise a metal.

Embodiment (c). The uLED device of embodiment (a) or (b), wherein the die n-contacts, the wafer n-contacts, the die p-contacts and the wafer p-contacts comprise the same metal.

Embodiment (d). The uLED device of any of embodiments (a) to (c), wherein the die n-contacts, the wafer n-contacts, the die p-contacts and the wafer p-contacts comprise one or more of: copper (Cu), aluminum (Al), nickel (Ni), titanium (Ti), titanium-tungsten (TiW), silver (Ag), gold (Au), platinum (Pt), and palladium (Pd).

Embodiment (e). The uLED device of any of embodiments (a) to (d), wherein the die dielectric material and the wafer dielectric material comprise the same dielectric material.

Embodiment (f). The uLED device of any of embodiments (a) to (e), wherein the die dielectric material and the wafer dielectric material comprise one or more of: silicon oxide (SiO), silicon dioxide (SiO₂), silicon nitride (SiN), silicon carbide (SiC), aluminum oxide (Al₂O₃), and aluminum nitride (AlN).

Embodiment (g). The uLED device of any of embodiments (a) to (f), wherein the uLED die further comprises a die substrate in contact with the semiconductor layers including the active region.

Embodiment (h). The uLED device of embodiment (g), wherein the die substrate comprises a material selected from the group consisting of: a sapphire, silicon carbide, and III-nitride.

Embodiment (i). The uLED device of any of embodiments (a) to (h), wherein the target substrate comprises a substrate material selected from the group consisting of: ceramic, silicon, aluminum, a sapphire, silicon carbide, and III-nitride.

Embodiment (j). The uLED device of any of embodiments (a) to (i) further comprising an etch stop layer on the target substrate below the wafer n-contacts, the wafer p-contacts, and the wafer dielectric material.

Embodiment (k). The uLED device of embodiment (j), wherein the etch stop layer comprises a dielectric material different from the wafer dielectric material.

Embodiment (l). The uLED device of any of embodiments (a) to (k), wherein the wafer n-contacts are directly bonded to the plurality of die n-contacts over respective n-contact bond areas and the wafer p-contacts are directly bonded to the die p-contacts over respective p-contact bond areas, and wherein diameters of the n-contact bond areas and the p-contact bond areas have a diameter in a range of 0.5 micrometers to less than or equal to 30 micrometers.

Embodiment (m). The uLED device of any of embodiments (a) to (l), wherein the wafer n-contacts are directly bonded to the plurality of die n-contacts over respective n-contact bond areas and the wafer p-contacts are directly bonded to the die p-contacts over respective p-contact bond areas, and wherein a pitch between centers of all of the n-contact bond areas and the p-contact bond areas is in a range of greater than or equal to 1 micrometers to less than or equal to 60 micrometers.

Embodiment (n). The uLED device of any of embodiments (a) to (m), wherein the die n-contacts and the die p-contacts are connected in series to the wafer n-contacts and the wafer p-contacts.

Embodiment (nn). The uLED device of any of embodiments (a) to (n), wherein a width of each of the wafer n-contacts is 95% to 100% of a width of each of the die n-contacts at each location where they are directly bonded; and/or a width of each of the wafer p-contacts is 95% to 100% of a width of each of the die p-contacts at each location where they are directly bonded; and/or a width of the wafer dielectric material is 95% to 100% of a width of the die dielectric material at each location where they are directly bonded.

Embodiment (o). A method of manufacturing a micro-light emitting diode (uLED) device comprising: preparing a target wafer comprising: a target substrate on which a plurality of wafer n-contacts, a plurality of wafer p-contacts, and a wafer dielectric material are located by: depositing an etch stop layer on the target substrate; depositing a primary dielectric material on the target substrate; preparing a dielectric material mask on the target substrate, etching the primary dielectric material, and removing the dielectric material mask; preparing a primary metal contact layer on the target substrate; planarizing a preliminary surface of the target substrate; depositing a secondary dielectric material layer on the target substrate, positioning a contact mask on the target substrate, etching the secondary dielectric material, and removing the contact mask; preparing a secondary metal contact layer on the target substrate; planarizing a second surface of the target substrate to form the plurality of wafer n-contacts and the plurality of wafer p-contacts, which are isolated by the wafer dielectric material; bonding a source wafer to the target wafer, the source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts, and upon bonding, the plurality of the wafer n-contacts are directly bonded to the plurality of die n-contacts; the plurality of wafer p-contacts are directly bonded to the die p-contacts; and the wafer dielectric material directly is bonded to the die dielectric material.

Embodiment (p). The method of embodiment (o), wherein the wafer n-contacts are directly bonded to the plurality of die n-contacts over respective n-contact bond areas and the wafer p-contacts are directly bonded to the die p-contacts over respective p-contact bond areas, and wherein diameters of the n-contact bond areas and the p-contact bond areas have a diameter in a range of 0.5 micrometers to less than or equal to 30 micrometers.

Embodiment (q). The method of embodiment (o) or (p), wherein the wafer n-contacts are directly bonded to the plurality of die n-contacts over respective n-contact bond areas and the wafer p-contacts are directly bonded to the die p-contacts over respective p-contact bond areas, and wherein a pitch between centers of all of the n-contact bond areas and the p-contact bond areas is in a range of greater than or equal to 1 micrometers to less than or equal to 60 micrometers.

Embodiment (r). The method of any of embodiments (o) to (q), wherein the preparing of the primary metal contact layer and the preparing of the secondary metal contact layer independently comprise: depositing a seed layer and conducting metal plating on the seed layer.

Embodiment(s). The method of any of embodiments (o) to (r), wherein the planarizing of the preliminary surface of the target substrate and of the second surface of the target substrate independently comprise a planarity of less than or equal to 5 Å.

Embodiment (t). The method of any of embodiments (o) to(s), wherein the planarizing of the preliminary surface of the target substrate and of the second surface of the target substrate independently comprise a chemical mechanical polishing (CMP) process.

Embodiment (u). The method of any of embodiments (o) to (t), further comprising a cleaning process after one or more both of the planarizing of the preliminary surface of the target substrate and of the second surface of the target substrate.

Embodiment (v). The method of any of embodiments (o) to (u), wherein upon the bonding of uLED die to the target wafer, the die n-contacts and the die p-contacts are connected in series to the wafer n-contacts and the wafer p-contacts.

Embodiment (w). Any of the embodiments (a) to (v), wherein each uLED has at least one characteristic dimension of greater than or equal to 1 micrometer less than or equal to 300 micrometers, the characteristic dimension being selected from the group consisting of: height, width, depth, thickness, and combinations thereof.

Embodiment (x). Any of the embodiments (a) to (w), wherein for each uLED a p-contact and an n-contact are formed on a same side of a pixel or stack of semiconductor layers.

Embodiment (y). A source wafer comprising: a uLED die including: a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts; each of the die n-contacts and the die p-contacts having a contact opening having a diameter “d” and a center “c”, and a pitch “p” between adjacent centers of each of the die n-contacts and the die p-contacts, the “d” being in a range of greater than or equal to 0.5 micrometers and less than or equal to 30 micrometers, and the “p” being in a of greater than or equal to 1 micrometer and less than or equal to 60 micrometers.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A micro-light emitting diode (uLED) device comprising:
a source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts;
a target wafer comprising: a target substrate on which a plurality of wafer n-contacts, a plurality of wafer p-contacts, and a wafer dielectric material are located, the wafer n-contacts directly bonded to the plurality of die n-contacts; the wafer p-contacts directly bonded to the die p-contacts; and the wafer dielectric material directly bonded to the die dielectric material; the wafer dielectric material isolating the wafer n-contacts and the wafer p-contacts.

2. The uLED device of claim 1, wherein a width of each of the wafer n-contacts is 95% to 100% of a width of each of the die n-contacts at each location where they are directly bonded; and/or a width of each of the wafer p-contacts is 95% to 100% of a width of each of the die p-contacts at each location where they are directly bonded; and/or a width of the wafer dielectric material is 95% to 100% of a width of the die dielectric material at each location where they are directly bonded.

3. The uLED device of claim 1, wherein the die n-contacts, the wafer n-contacts, the die p-contacts and the wafer p-contacts comprise a metal.

4. The uLED device of claim 1, wherein the die n-contacts, the wafer n-contacts, the die p-contacts and the wafer p-contacts comprise the same metal.

5. The uLED device of claim 1, wherein the die n-contacts, the wafer n-contacts, the die p-contacts and the wafer p-contacts comprise one or more of: copper (Cu), aluminum (Al), nickel (Ni), titanium (Ti), titanium-tungsten (TiW), silver (Ag), gold (Au), platinum (Pt), and palladium (Pd).

6. The uLED device of claim 1, wherein the die dielectric material and the wafer dielectric material comprise the same dielectric material.

7. The uLED device of claim 1, wherein the die dielectric material and the wafer dielectric material comprise one or more of: silicon oxide (SiO), silicon dioxide (SiO2), silicon nitride (SiN), silicon carbide (SiC), aluminum oxide (Al2O3), and aluminum nitride (AlN).

8. The uLED device of claim 1, wherein the uLED die further comprises a die substrate in contact with the semiconductor layers including the active region.

9. The uLED device of claim 8, wherein the die substrate comprises a material selected from the group consisting of: a sapphire, silicon carbide, and III-nitride and/or the target substrate comprises a substrate material selected from the group consisting of: ceramic, silicon, aluminum, a sapphire, silicon carbide, and III-nitride.

10. (canceled)

11. The uLED device of claim 1 further comprising an etch stop layer on the target substrate below the wafer n-contacts, the wafer p-contacts, and the wafer dielectric material.

12. The uLED device of claim 1, wherein the wafer n-contacts are directly bonded to the plurality of die n-contacts over respective n-contact bond areas and the wafer p-contacts are directly bonded to the die p-contacts over respective p-contact bond areas, and wherein diameters of the n-contact bond areas and the p-contact bond areas have a diameter in a range of 0.5 micrometers to less than or equal to 30 micrometers.

13. The uLED device of claim 1, wherein the wafer n-contacts are directly bonded to the plurality of die n-contacts over respective n-contact bond areas and the wafer p-contacts are directly bonded to the die p-contacts over respective p-contact bond areas, and wherein a pitch between centers of all of the n-contact bond areas and the p-contact bond areas is in a range of greater than or equal to 1 micrometers to less than or equal to 60 micrometers.

14. The uLED device of claim 1, wherein the die n-contacts and the die p-contacts are connected in series to the wafer n-contacts and the wafer p-contacts.

15. A method of manufacturing a micro-light emitting diode (uLED) device comprising:
preparing a target wafer comprising: a target substrate on which a plurality of wafer n-contacts, a plurality of wafer p-contacts, and a wafer dielectric material are located by:
depositing an etch stop layer on the target substrate;
depositing a primary dielectric material on the target substrate;
preparing a dielectric material mask on the target substrate, etching the primary dielectric material, and removing the dielectric material mask;
preparing a primary metal contact layer on the target substrate;
planarizing a preliminary surface of the target substrate;
depositing a secondary dielectric material layer on the target substrate, preparing a contact mask on the target substrate, etching the secondary dielectric material, and removing the contact mask;
preparing a secondary metal contact layer on the target substrate; and
planarizing a second surface of the target substrate to form the plurality of wafer n-contacts and the plurality of wafer p-contacts, which are isolated by the wafer dielectric material;
bonding a source wafer to the target wafer, the source wafer comprising: a uLED die including a plurality of pixels each having sidewalls and comprising a mesa of semiconductor layers including an active region; a plurality of die n-contacts in electrical communication with an n-type layer of the mesa; a plurality of die p-contacts in communication with a p-type layer of the mesa; and a die dielectric material isolating the die n-contacts and the die p-contacts, and
upon bonding, the plurality of the wafer n-contacts are directly bonded to the plurality of die n-contacts; the plurality of wafer p-contacts are directly bonded to the die p-contacts; and the wafer dielectric material directly is bonded to the die dielectric material.

16. The method of claim 15, wherein the wafer n-contacts are directly bonded to the plurality of die n-contacts over respective n-contact bond areas and the wafer p-contacts are directly bonded to the die p-contacts over respective p-contact bond areas, and wherein diameters of the n-contact bond areas and the p-contact bond areas have a diameter in a range of 0.5 micrometers to less than or equal to 30 micrometers, and/or wherein a pitch between centers of all of the n-contact bond areas and the p-contact bond areas is in a range of greater than or equal to 1 micrometers to less than or equal to 60 micrometers.

17. (canceled)

18. The method of claim 15, wherein the preparing of the primary metal contact layer and the preparing of the secondary metal contact layer independently comprise: depositing a seed layer and conducting metal plating on the seed layer.

19. The method of claim 15, wherein the planarizing of the preliminary surface of the target substrate and of the second surface of the target substrate independently comprise a planarity of less than or equal to 5 Å, and/or the planarizing of the preliminary surface of the target substrate and of the second surface of the target substrate independently comprise a chemical mechanical polishing (CMP) process.

20. (canceled)

21. The method of claim 15, further comprising a cleaning process after one or more both of the planarizing of the preliminary surface of the target substrate and of the second surface of the target substrate.

22. The method of claim 15, wherein upon the bonding of uLED die to the target wafer, the die n-contacts and the die p-contacts are connected in series to the wafer n-contacts and the wafer p-contacts.

23. A source wafer comprising: a uLED die including:
a plurality of pixels each having sidewalls and comprising a mesa of semiconductor layers including an active region;
a plurality of die n-contacts in electrical communication with an n-type layer of the mesa;
a plurality of die p-contacts in communication with a p-type layer of the mesa; and
a die dielectric material isolating the die n-contacts and the die p-contacts;
each of the die n-contacts and the die p-contacts having a contact opening having a diameter “d” and a center “c”, and a pitch “p” between adjacent centers of each of the die n-contacts and the die p-contacts, the “d” being in a range of greater than or equal to 0.5 micrometers and less than or equal to 30 micrometers, and the “p” being in a of greater than or equal to 1 micrometer and less than or equal to 60 micrometers.
